(19) United States
(12) Patent Application Publication
(10) Pub. No.: US 2016/0020143 A1
(43) Pub. Date: Jan. 21, 2016

(54) Semiconductor Devices and Fabrication Methods With Reduced Topology And Reduced Word Line Stringer Residual Material

(71) Applicant: Macronix International Co., Ltd., Hsinchu (TW)

(72) Inventors: Chien-Ying Lee, New Taipei City (TW); Chih-Hsiung Lee, Hsinchu City (TW); Tzung-Ting Han, Hsinchu City (TW)

(21) Appl. No.: 14/334,363

(22) Filed: Jul. 17, 2014

(51) Int. Cl. H01L 21/768; H01L 23/532

(52) U.S. Cl. CPC H01L 21/76843; H01L 21/76802; H01L 23/53257

(57) ABSTRACT

Provided are improved semiconductor memory devices and methods for manufacturing such semiconductor memory devices. A method may incorporate the formation of a first dielectric layer over buried oxide regions and the removal of such dielectric layer to prepare a substantially planar substrate for subsequent formation of word lines. The method may allow for the production of semiconductor memory devices of reduced size with reduced word line stringer residual material.

### TECHNOLOGICAL FIELD

The present invention generally relates to structures of a semiconductor device and methods of forming the semiconductor device. In particular, the present invention relates to an improved memory device and method for manufacturing such a memory device.

### BACKGROUND

A flash memory device generally includes an array of memory cells arranged in rows and columns. Each memory cell includes a transistor structure having a gate, a drain, a source, and a channel defined between the drain and the source. The gate corresponds to a word line, and the drain or source correspond to bit lines of the memory array. The gate of a conventional flash memory cell is generally a dual-gate structure, including a control gate and a floating gate, wherein the floating gate is sandwiched between two dielectric layers to trap carriers such as electrons, to program the cell.

The semiconductor industry is increasingly driven towards smaller and more capable electronic devices, such as computing devices, communication devices, and memory devices. In order to reduce the size of such devices, while maintaining or improving their respective capabilities, the size of components within the devices must be reduced. However, issues arise with such reduction.

Applicant has identified deficiencies and problems associated with conventional processes for manufacturing memory devices and the resulting memory devices. For instance, with regards to flash memory devices, as the cell size is reduced, issues arise that prevent further reduction in size while maintaining the cell's capabilities and respective function. Traditional processing results in a large topology over the memory cell. This variation is in part due to the presence of buried diffusion oxide regions. As word lines are formed and etched into the desired structure, unwanted residual material may remain in crevices or along edges due to the large topology. This residual material is known as “stringers.” These “stringers” become more of an issue as the size of word lines and/or the space between those word lines is reduced.

Through applied effort, ingenuity, and innovation, certain of these identified problems have been solved by developing solutions that are included in various embodiments of the present invention, which are described in detail below.

### BRIEF SUMMARY OF EXEMPLARY EMBODIMENTS

Embodiments of the present invention therefore provide methods of manufacturing semiconductor devices useful in the manufacture of memory devices, especially those reduced in size, and provide semiconductor memory devices resulting from such method.

The present invention provides a method of manufacturing a semiconductor device that has reduced topology and, thus, reduced word line stringer issues and a semiconductor device produced from such method. The present invention provides the ability to reduce the size of a flash memory device. For instance, in the embodiment of FIG. 8A, after removing the first dielectric fill material, the substrate is substantially planar. Without intending to be bound by theory, the reduced topology allows for the subsequent deposition and formation of the word lines without the formation of undesired residual material, or “stringers.”

An aspect of the invention provides a method of fabricating a semiconductor memory device. In certain embodiments of the invention, the method of fabricating a semiconductor memory device comprises the steps of providing a substrate, a buffer layer, and a hard mask layer; foaming a buried diffusion region in the substrate; depositing a first dielectric fill material along the substrate; removing excess first dielectric fill material above the hard mask layer; performing self-aligned patterning to form at least one trench in a self-aligned contact region of the semiconductor; depositing a second dielectric fill material along substrate; removing excess second dielectric fill material above the hard mask layer; removing the hard mask layer; and removing the first dielectric fill material.

In one embodiment of the invention, the method of fabricating a semiconductor memory device comprises applying a photo resist layer to at least a portion of the semiconductor prior to performing self-aligned patterning. In certain embodiments of the invention, the method of fabricating a semiconductor memory device comprises the steps of removing the photo resist layer after performing self-aligned patterning.

In an embodiment of the invention, the method of fabricating a semiconductor memory device may further comprise the step of depositing a first dielectric layer after removing the first dielectric fill material. In one embodiment of the invention, the method of fabricating a semiconductor memory device may comprise the step of depositing a first conductive layer along the first dielectric layer. In another embodiment of the invention, the method of fabricating a semiconductor memory device may comprise the step of forming a second conductive layer along the first conductive layer. In yet a further embodiment of the invention, the method of fabricating a semiconductor memory device may comprise the step of etching at least one word line in the semiconductor.

In an embodiment of the invention, the buried diffusion region may be formed by implanting ions in the substrate. In certain embodiments of the invention, the buried diffusion region may be formed by doping the substrate with N-type dopants.

In one embodiment of the invention, the step of depositing the first dielectric fill material may comprise depositing an oxide such as silicon oxide. In an embodiment of the invention, the removal of excess first dielectric material may comprise chemical-mechanical polishing resulting in planarization of the first dielectric fill material. In one embodiment of the invention, the removal of the first dielectric fill material may comprise etching. In certain embodiments, the removal of the first dielectric fill material may comprise etching the semiconductor with an etchant with a high selectivity to silicon.

In one embodiment of the invention depositing the first dielectric layer may comprise depositing an oxide-nitride-oxide layer. In some embodiments of the invention, depositing the first conductive layer along the first dielectric layer may comprise depositing polysilicon. In another embodiment of the invention, forming the second conductive layer may comprise forming a tungsten silicide layer.

An aspect of the invention also provides a semiconductor device comprising a substrate; a buried diffusion region in the substrate, wherein the substrate and buried diffusion region have a reduced topology; and a word line disposed along the substrate and the buried diffusion region.

According to an embodiment of the invention, the first dielectric layer may comprise an oxide-nitride-oxide layer. In certain embodiments of the invention, the word line comprises a first conductive layer and a second conductive layer. According to certain embodiments of the invention, the first conductive layer may comprise polysilicon. In one embodiment of the invention, the second conductive layer may comprise tungsten silicide.

In certain embodiments, the buried diffusion region may comprise arsenic ions.

These embodiments of the present invention and other aspects and embodiments of the present invention are described further herein and will become apparent upon review of the following description taken in conjunction with the accompanying drawings.

### BRIEF DESCRIPTION OF THE SEVERAL VIEWS OF THE DRAWINGS

Having thus described the invention in general terms, reference will now be made to the accompanying drawings, which are not necessarily drawn to scale, and wherein:

FIG. 1 illustrates a cross-section of a semiconductor undergoing ion implantation according to an embodiment of the invention;

FIG. 2 illustrates a cross-section of a semiconductor after deposition of a first dielectric fill material according to an embodiment of the invention;

FIG. 3 illustrates a cross-section of a semiconductor after removing excess first dielectric fill material according to an embodiment of the invention;

FIG. 4A illustrates a top view of a semiconductor after application of a photo resist layer according to an embodiment of the invention;

FIGS. 4B-4C illustrate two cross-sections of a semiconductor after applying a photo resist layer to at least a portion of the semiconductor and performing self-aligned patterning to form at least one trench in the self-aligned contact region according to an embodiment of the invention;

FIG. 4D illustrates a top view of a semiconductor after performing self-aligned patterning and after removal of a photo resist layer according to an embodiment of the invention;

FIGS. 5A-5B illustrate two cross-sections of a semiconductor after deposition of a second dielectric fill material according to an embodiment of the invention;

FIGS. 6A-6C illustrate various regions and views of a semiconductor after excess second dielectric fill material is removed according to an embodiment of the invention;

FIGS. 7A-7C illustrate various regions and views of a semiconductor after removal of the hard mask layer according to an embodiment of the invention;

FIGS. 8A-8C illustrate various regions and views of a semiconductor after removal of the first dielectric fill material according to an embodiment of the invention;

FIGS. 9A-9B illustrate two cross-sections of a semiconductor after deposition of a first dielectric layer, a first conductive layer, and a second conductive layer according to an embodiment of the invention;

FIGS. 10A-10D illustrate various regions and views of a semiconductor after etching a plurality of word lines according to an embodiment of the invention;

FIG. 11 is a perspective view of a portion of a semiconductor after etching at least two word lines according to an embodiment of the invention;

FIG. 12 shows a process flow chart for a method of forming a semiconductor memory device according to an embodiment of the invention; and

FIG. 13 is a continuation of the process flow chart for the method of forming a semiconductor memory device depicted in FIG. 12 according to an embodiment of the invention.

### DETAILED DESCRIPTION

The present invention now will be described more fully hereinafter with reference to the accompanying drawings, in which some, but not all embodiments of the inventions are shown. Indeed, these inventions may be embodied in many different forms and should not be construed as limited to the embodiments set forth herein; rather, these embodiments are provided so that this disclosure will satisfy applicable legal requirements. Like numbers refer to like elements throughout.

Non-volatile memory refers to a semiconductor device which is able to store information even when the supply of electricity is removed from the memory. Non-volatile memory includes, without limitation, Mask Read-Only Memory, Programmable Read-Only Memory, Erasable Programmable Read-Only Memory, Electrically Erasable Programmable Read-Only Memory, and Flash Memory.

As used herein, a “substrate” may include any underlying material or materials upon which a device, a circuit, an epitaxial layer, or a semiconductor may be formed. Generally, a substrate may be used to define the layer or layers that underlie a semiconductor device or even forms the base layer of a semiconductor device. Without intending to be limiting, the substrate may include one or any combination of silicon, doped silicon, germanium, silicon germanium, semiconductor compounds, or other semiconductor materials.

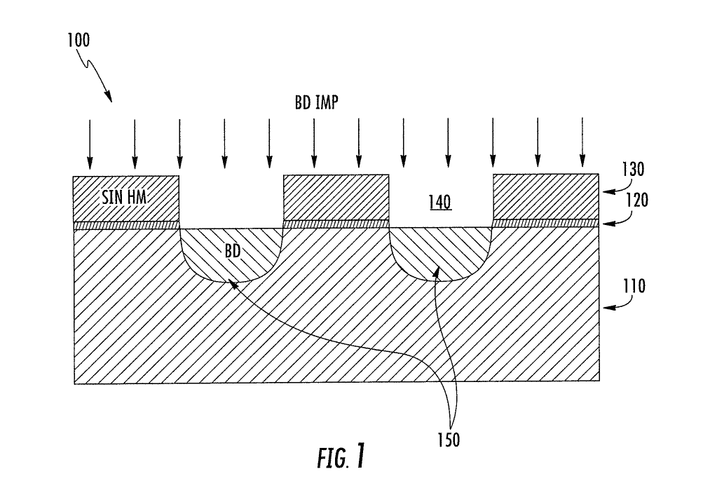

FIG. 1 illustrates a cross-section of a semiconductor undergoing ion implantation according to an embodiment of the invention. The depicted semiconductor 100 comprises a substrate 110, a buffer layer 120, and a hard mask layer 130. The buffer layer may comprise silicon oxide (SiO₂), silicon oxynitride (SiOₓN_{y}), or any combination thereof. The hard mask layer may be any layer that prevents ion implantation in the covered region. For instance, the hard mask layer may be a nitride layer, such as silicon nitride (Si₃N₄).

The buffer layer may be formed by any suitable deposition process, such as chemical vapor deposition (CVD) or spin-on dielectric processing. The hard mask layer may be formed by any suitable process, such as CVD or spin-on dielectric processing. For instance, the buffer layer and/or the hard mask layer may be formed by an enhanced high aspect ratio process (eHARP) chamber for chemical vapor deposition; high density plasma deposition such as high density plasma chemical vapor deposition; plasma enhanced oxide (PEOX) process; undoped silicon glass using, for example, chemical vapor deposition; tetraethoxysilane (TEOS) deposition; or hot temperature oxide (HTO) film deposition.

In the embodiment of FIG. 1, the hard mask layer 130 and buffer layer 120 have been etched to form etched regions 140 in the semiconductor 100. In certain embodiments, the substrate 110 may be etched as well. In some embodiments, etching may be performed by wet or dry etching. Non-limiting examples of wet etch processes include chemical vapor etching, metal assisted etching, and electroless etching. For example, chemical vapor etching may be performed using an acidic etching solution such as mixtures comprising HNO₃ and/or HF. In certain embodiments, the wet etch process may be a buffered oxide etch process or a buffered hydrofluoric acid process. Non-limiting examples of dry etching processes include plasma etching, sputter etching, ionization etching, and reactive ion etching.

Ions may then be implanted in the etched regions 140 to form a buried diffusion region 150. In the embodiment of FIG. 1, the step of implanting ions (buried diffusion (“BD”) implantation (“IMP”)) results in a buried diffusion region 150 (buried diffusion (“BD”)) in the substrate 110. In certain embodiments of the invention, the buried diffusion region may be formed by doping the substrate with n-type dopants. For instance, in some embodiments, the substrate may be doped with arsenic ions to form a buried diffusion reigon. In some embodiments, the substrate may be doped with phosphorus ions. In one embodiment, the substrate may be doped with a combination of dopants. The hard mask layer 130 may prevent ion diffusion in regions covered by the hard mask layer 130.

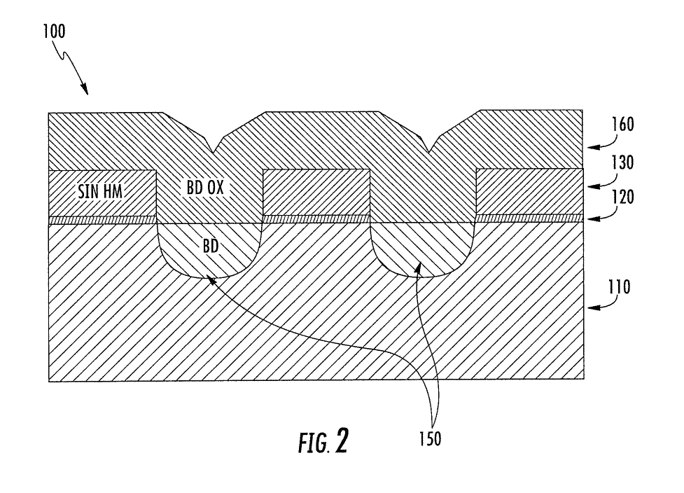

Following formation of the buried diffusion region 150, a first dielectric fill material may be formed along the semiconductor. FIG. 2 illustrates a cross-section of a semiconductor after deposition of a first dielectric fill material according to an embodiment of the invention. In FIG. 2, a first dielectric fill material 160 (buried diffusion oxide “BD OX”) is applied over the substrate 110. The first dielectric layer 160 may be any one of silicon oxide (SiO₂), silicon oxynitride (SiOₓN_{y}), or any combination thereof. In some embodiments, the first dielectric fill material may comprise one or more layers of dielectric material. In the embodiment of FIG. 2, the first dielectric fill material substantially fills the etched regions 140 and covers the buried diffusion region 150.

The first dielectric fill material may be formed by any suitable deposition process, such as CVD or spin-on dielectric processing. For instance, the first dielectric fill material may be formed by an enhanced high aspect ratio process (eHARP) chamber for chemical vapor deposition; high density plasma deposition such as high density plasma chemical vapor deposition; plasma enhanced oxide (PEOX) process; undoped silicon glass using, for example, chemical vapor deposition; tetraethoxysilane (TEOS) deposition; or hot temperature oxide (HTO) film deposition.

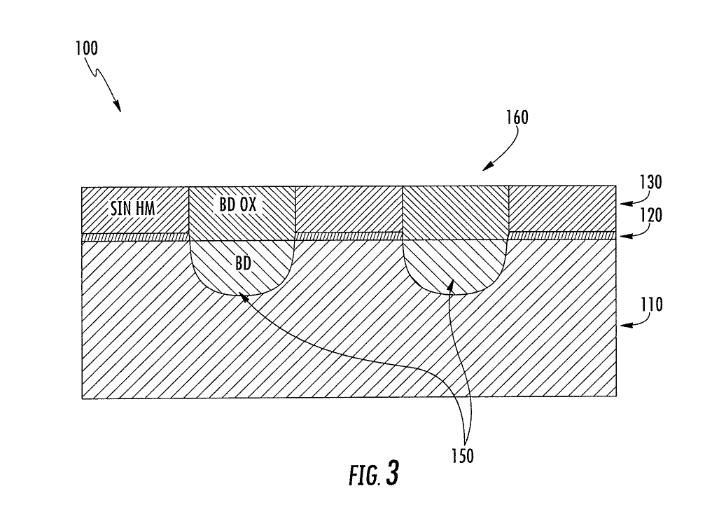

In some embodiments of the invention, excess first dielectric fill material may be removed. For example, the first dielectric material 160 covering the hard mask layer 130 may be removed. In certain embodiments of the invention, first dielectric fill material 160 covering the hard mask layer 130 may be removed to planarize the surface of the semiconductor. FIG. 3 illustrates a cross-section of a semiconductor 100 after removing excess first dielectric fill material 160 according to an embodiment of the invention. In certain embodiments, excess first dielectric fill material 160 may be removed by chemical-mechanical polishing. As illustrated in FIG. 3, the hard mask layer 130 may serve as a stop-etch to prevent further polishing. In one embodiment, excess first dielectric fill material 160 may be removed by a combination of polishing and etching steps, or by etching alone. The etching process may be wet or dry etching as previously defined. In some embodiments, at least a portion of the excess first dielectric fill material may be removed by a selective etching process where the first dielectric layer is preferably removed.

In certain embodiments, it may be desirable to form trenches in a region of the semiconductor. In some embodiments, a plurality of trenches may be formed. In an embodiment of the invention, one or more trench may be formed utilizing photolithography and self-aligned patterning. Photolithography or optical lithography involves the use of a light sensitive polymer or a photo resist that is exposed and developed to form three-dimensional patterning on a substrate. The general sequence for a photolithography process may include the steps of preparing the substrate, applying a photo resist, prebaking, exposing, post-exposure baking, developing, and post-baking. Photo resists may be applied to the substrate by any number of techniques, such as spin coating. Generally, it may be important to establish a uniform thickness of the photo resist across the substrate. Optionally, a layer of bottom anti-reflectivity coating (BARC) may be applied to the substrate prior to the application of the photo resist layer. Adhesion promoters may be applied to the substrate prior to application of the photo resist.

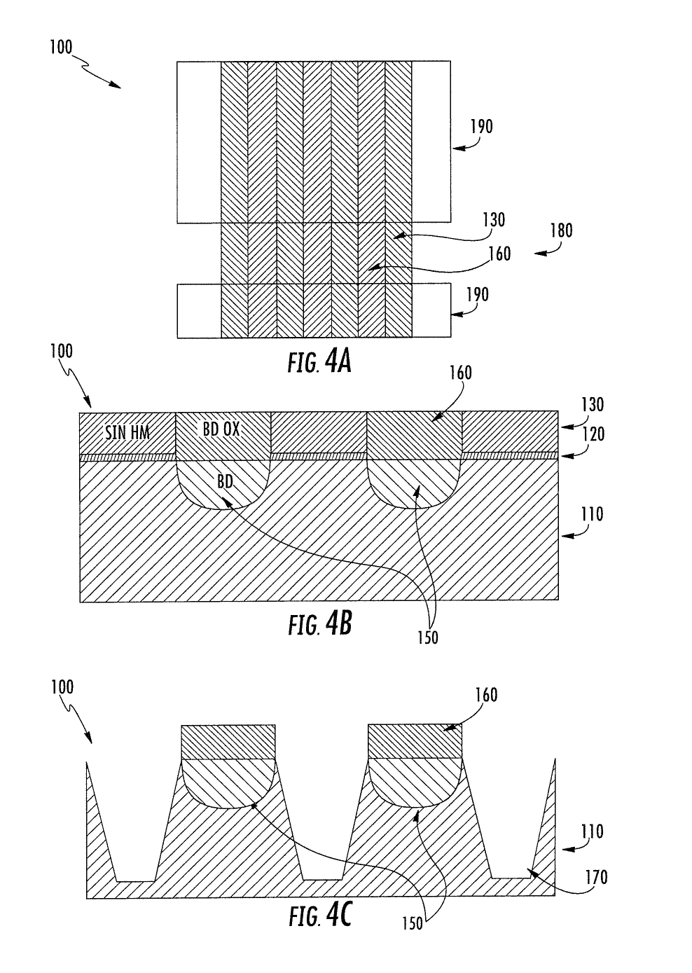

According to certain embodiments of the invention, self-aligned patterning may be used to form a self-aligned contact region in the semiconductor. FIGS. 4A-4D illustrate various regions and views of a semiconductor during the steps of applying a photo resist layer to at least a portion of the semiconductor, performing self-aligned patterning to form at least one trench in the self-aligned contact region, and removing the photo resist layer according to an embodiment of the invention. Specifically, FIG. 4A illustrates a top view of a semiconductor after application of a photo resist layer according to an embodiment of the invention. FIGS. 4B-4C illustrate two cross-sections of a semiconductor after applying a photo resist layer to at least a portion of the semiconductor and performing self-aligned patterning to form at least one trench in the self-aligned contact region according to an embodiment of the invention. FIG. 4D illustrates a top view of a semiconductor after performing self-aligned patterning and after removal of a photo resist layer according to an embodiment of the invention.

In the embodiment of FIG. 4A, a photo resist layer 190 is applied to the semiconductor 100. The photo resist may undergo steps of prebaking, exposing, post-exposure baking, developing, and post-baking. After processing, only certain desired portions of the semiconductor remain covered by the photo resist layer. In some embodiments, only a portion of the semiconductor is covered by a photoresist layer, while in other embodiments, several areas of the semiconductor are covered by a photoresist layer. The parts of the substrate that remain covered with the photo resist will be protected from subsequent etching, ion implantation, and/or certain other processing techniques.

In certain embodiments of the invention, the uncovered portions of the semiconductor may be etched to form trenches 170 in the substrate 110. After etching, the photo resist may be removed, leaving a self-aligned contact region in the semiconductor. FIG. 4D illustrates the self-aligned contact region 180 in the semiconductor 100. The self-aligned contact region 180 comprises trenches 170 adjacent to the buried oxide regions 150 and first dielectric fill material 160.

FIG. 4B illustrates a cross-section of a portion of the semiconductor that remained covered by a photo resist layer during self-aligned patterning. As shown in FIG. 4B, the substrate 110 is not etched to form trenches. FIG. 4C illustrates the uncovered areas which are etched to form trenches 170. In the embodiment of FIG. 4C, the trenches 170 are formed on either side of the buried oxide regions 150. Etching may be performed by any suitable etching process, such as wet or dry etching as described previously.

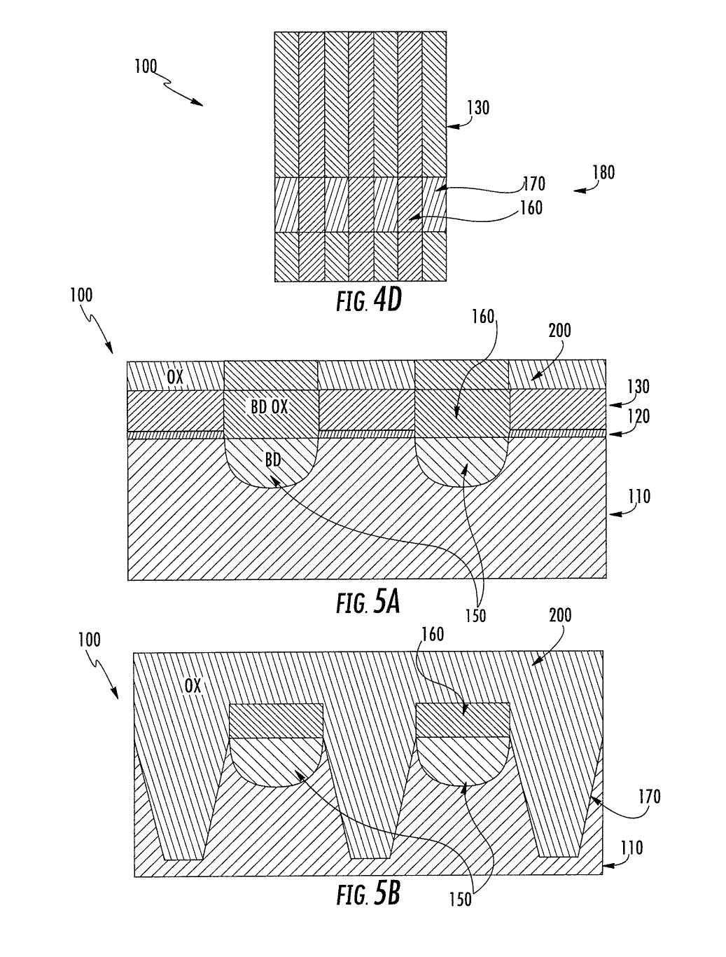

In certain embodiments, a second dielectric fill material 200 may then be applied to the semiconductor. FIGS. 5A-5B illustrate two cross-sections of a semiconductor 100 after deposition of a second dielectric fill material 200 according to an embodiment of the invention.

FIG. 5A illustrates a cross-section of a region that remained covered by a photoresist layer 120 during self-aligned patterning. FIG. 5B illustrates a cross-section of a self-aligned contact region of the semiconductor.

In certain embodiments, a second dielectric fill material 200 is applied over at least a portion of the substrate. In the embodiment shown in FIG. 5B, a second dielectric fill material 200 fills the trenches 170 in the substrate 110. The second dielectric fill material 170 may be any one of silicon oxide (SiO₂), silicon oxynitride (SiOₓN_{y}), or any combination thereof.

A second dielectric fill material may be applied by any suitable deposition process. For instance, a second dielectric fill material may be applied by a chemical vapor deposition process such as eHARP (enhanced High Aspect Ratio Process) or high density plasma chemical vapor deposition. In certain embodiments, a second dielectric fill material may be applied by a spin-on-dielectric process. For instance, a second dielectric fill material may be formed by an enhanced high aspect ratio process (eHARP) chamber for chemical vapor deposition; high density plasma deposition such as high density plasma chemical vapor deposition; plasma enhanced oxide (PEOX) process; undoped silicon glass using, for example, chemical vapor deposition; tetraethoxysilane (TEOS) deposition; or hot temperature oxide (HTO) film deposition.

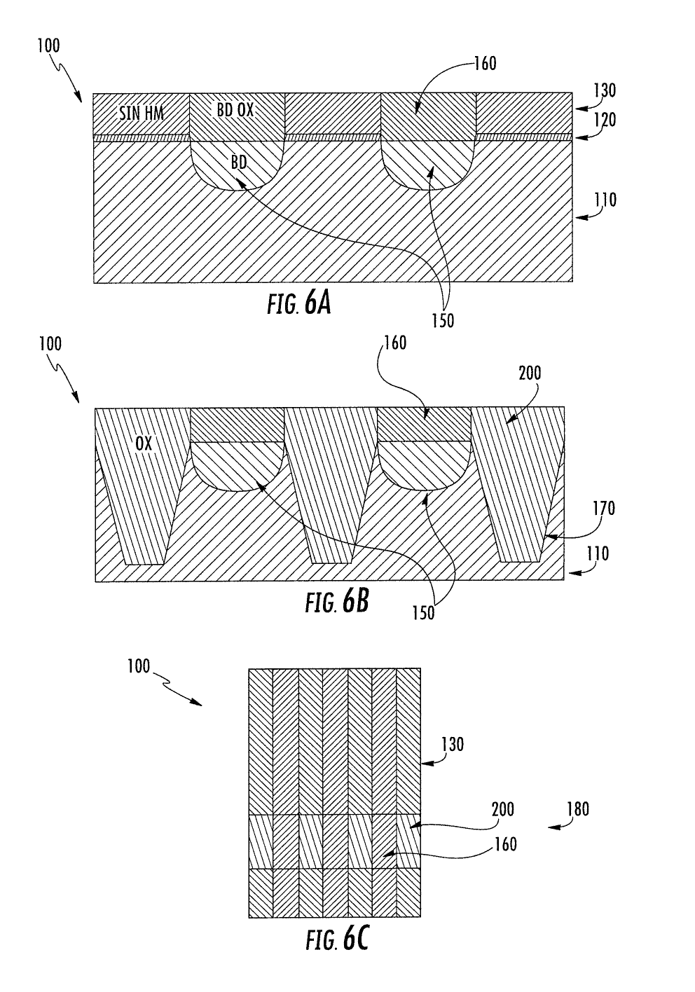

In some embodiments, excess second dielectric fill material may be removed. For example, the second dielectric material 200 covering the hard mask layer 130 may be removed. In certain embodiments of the invention, the second dielectric fill material 200 covering the hard mask layer 130 may be removed to planarize the surface of the semiconductor. In certain embodiments, excess second dielectric fill material 200 may be removed by chemical-mechanical polishing, etching, or any combination thereof. FIGS. 6A-6C illustrate various regions and views of a semiconductor after excess second dielectric fill material is removed according to an embodiment of the invention.

More particularly, FIG. 6A illustrates a cross-section of a region of a semiconductor 100 that remained covered by a photoresist layer during self-aligned patterning. As shown in FIG. 6A, the hard mask layer 130 prevents further removal of the first dielectric fill material allowing for a planarized surface.

FIG. 6B illustrates a cross-section of the self-aligned contact region 180 of the semiconductor 100. FIG. 6C illustrates a top view of a semiconductor 100 after removal of excess second dielectric fill material 200 according to an embodiment of the invention. FIG. 6C shows the second dielectric fill material 200 and the first dielectric fill material 160 in the self-aligned contact region 180 of the semiconductor 100.

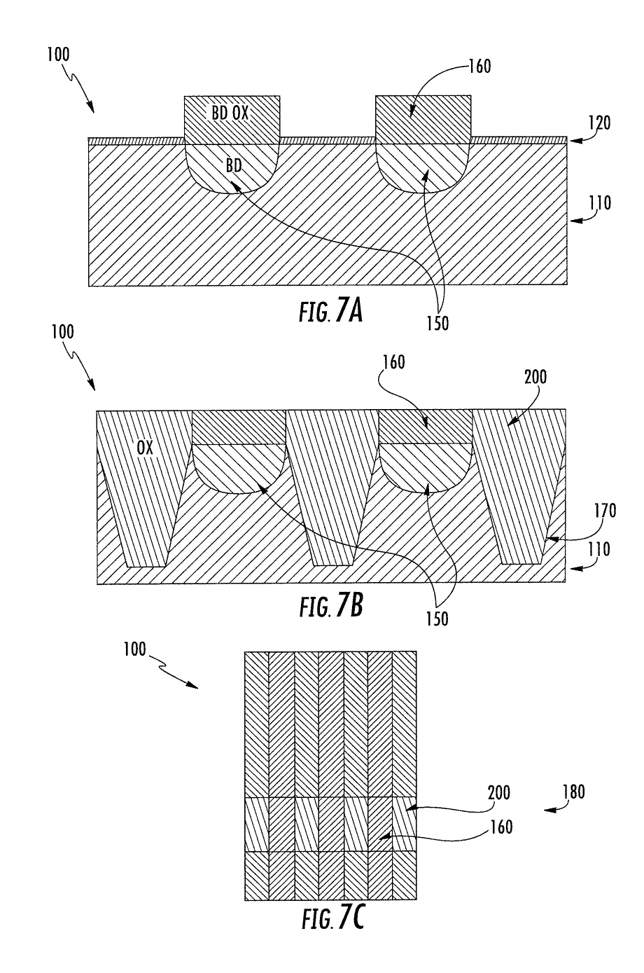

According to certain embodiments, the hard mask layer 130 may then be removed. FIGS. 7A-7C illustrate various regions and views of a semiconductor after removal of the hard mask layer 130 according to an embodiment of the invention.

FIG. 7A illustrates a cross-section of a region that remained covered by a photoresist layer during self-aligned patterning. FIG. 7B illustrates a cross-section of the self-aligned contact region 180 of the semiconductor 100. FIG. 7C illustrates a top view of a semiconductor 100 after removal of the hard mask layer 130.

As mentioned previously, a hard mask layer may be any suitable material that prevents ion diffusion in the covered region, such as silicon nitride. The hard mask layer also may prevent further polishing of the first dielectric fill material allowing for a planarized surface. The hard mask layer may be removed by any suitable removal method such as chemical-mechanical polishing, etching, or any combination thereof.

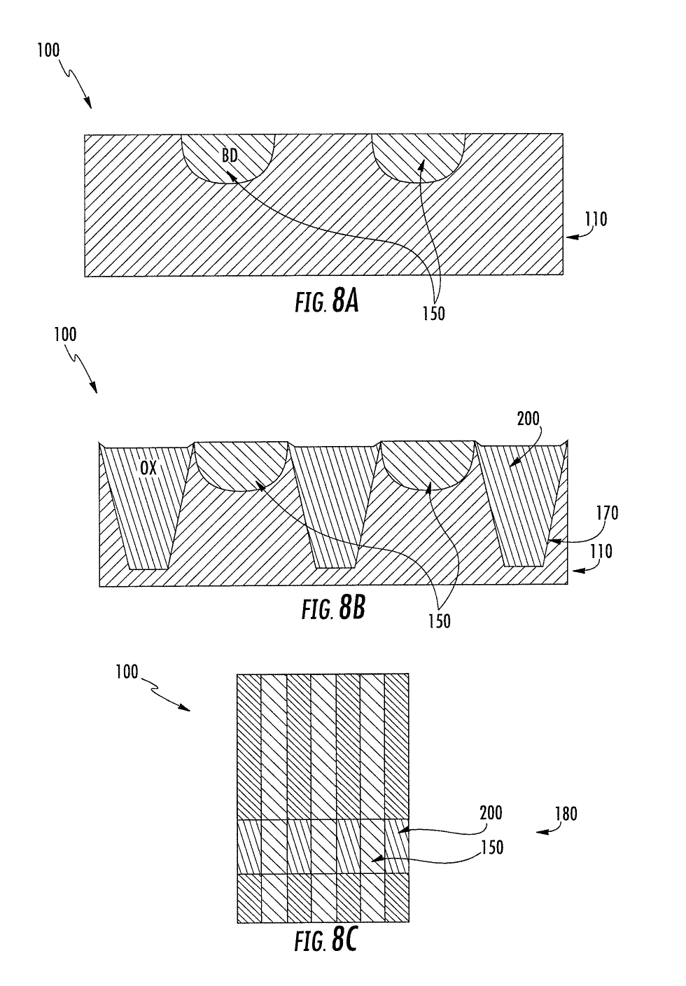

In certain embodiments of the invention, the first dielectric fill material may then be removed. In some embodiments, the removal of the first dielectric fill material provides a substantially planarized topology. In one embodiment, the buffer layer may be removed along with the first dielectric fill material. FIGS. 8A-8C illustrate various regions and views of a semiconductor after removal of the first dielectric fill material and buffer layer according to an embodiment of the invention.

In particular, FIG. 8A illustrates a cross-section of a region that remained covered by a photoresist layer during self-aligned patterning. FIG. 8B illustrates a cross-section of the self-aligned contact region 180 of the semiconductor 100. FIG. 8C illustrates a top view of a semiconductor 100 after removal of the first dielectric fill material 160 and buffer layer 120 according to an embodiment of the invention.

The first dielectric fill material may be removed by any suitable method. For instance, the first dielectric fill material may be removed by etching, such as wet etching or dry etching, or by chemical-mechanical polishing. In some embodiments, the first dielectric fill material may be removed by both etching and by chemical-mechanical polishing. In certain embodiments, the first dielectric fill material may be removed by a selective etching process. For instance, in embodiments where the first dielectric fill material comprises silicon oxide, the etching process may have a high selectivity to silicon.

In some embodiments, the buffer layer 120 may be removed along with the first dielectric layer 160. In other embodiments, the buffer layer may be partially removed along with the first dielectric layer and then removed completely by subsequent processing. The buffer layer may be removed by any suitable removal method such as chemical-mechanical polishing, etching, or any combination thereof.

In the embodiment of FIG. 8A, the removal of the first dielectric fill material and buffer layer results in a substantially planar topology. In flash memory devices, as the cell size of a flash memory device is reduced, issues arise that prevent further reduction in size while maintaining the cell's capabilities and respective function. Traditional processing results in a large topology over the memory cell. This variation is in part due to the presence of buried diffusion oxide regions. As word lines are formed and etched into the desired structure, unwanted residual material may remain in crevices or along edges due to the large topology. This residual material is known as “stringers.”

The present invention provides a method of manufacturing a semiconductor device that has reduced topology and, thus, reduced word line stringer issues and a semiconductor device produced from such method. The present invention provides the ability to reduce the size of a flash memory device. For instance, in the embodiment of FIG. 8A, after removing the first dielectric fill material, the substrate is substantially planar or has minimal surface defects. Without intending to be bound by theory, the reduced topology allows for the subsequent deposition and formation of the word lines without the formation of undesired residual material, or “stringers.”

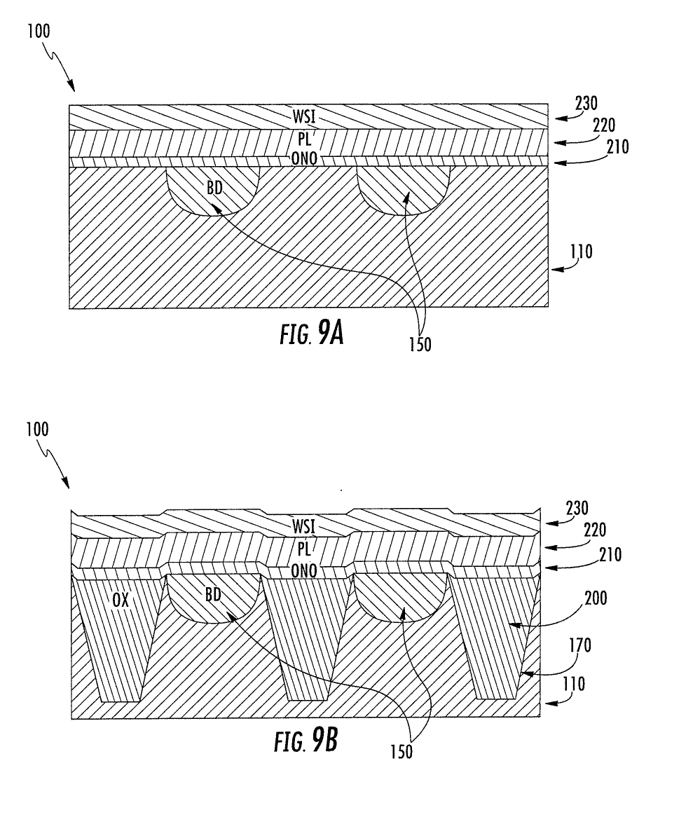

In certain embodiments of the invention, a first dielectric layer may be formed. In certain embodiments, a first conductive layer and second conductive layer may then be formed. FIGS. 9A-9B illustrate two cross-sections of a semiconductor 100 after deposition of a first dielectric layer 210, a first conductive layer 220, and a second conductive layer 230 according to an embodiment of the invention. The layers may be formed by any suitable deposition process such as CVD or spincoating. For instance the first dielectric layer may be formed by an enhanced high aspect ratio process (eHARP) chamber for chemical vapor deposition; high density plasma deposition such as high density plasma chemical vapor deposition; plasma enhanced oxide (PEOX) process; undoped silicon glass using, for example, chemical vapor deposition; tetraethoxysilane (TEOS) deposition; or hot temperature oxide (HTO) film deposition.

The first dielectric layer 210 may be any suitable dielectric, such as silicon oxide (SiO₂), silicon nitride (Si₃N₄), silicon oxynitride (SiOₓN_{y}), or any combination thereof. In the embodiment illustrated in FIG. 9A, the first dielectric layer comprises an oxide-nitride-oxide (ONO) layer. The first conductive layer 220 may comprise any suitable conductive material such as polysilicon. In the embodiment illustrated in FIG. 9A, the conductive layer comprises polysilicon. The second conductive layer 230 may comprise any suitable conductive material such as metal silicide. For instance, the second conductive layer may comprise tantalum silicide, titanium silicide, cobalt silicide, nickel silicide, platinum silicide, tungsten silicide, or any combination thereof. In the embodiment illustrated in FIG. 9A, the second conductive layer comprises tungsten silicide.

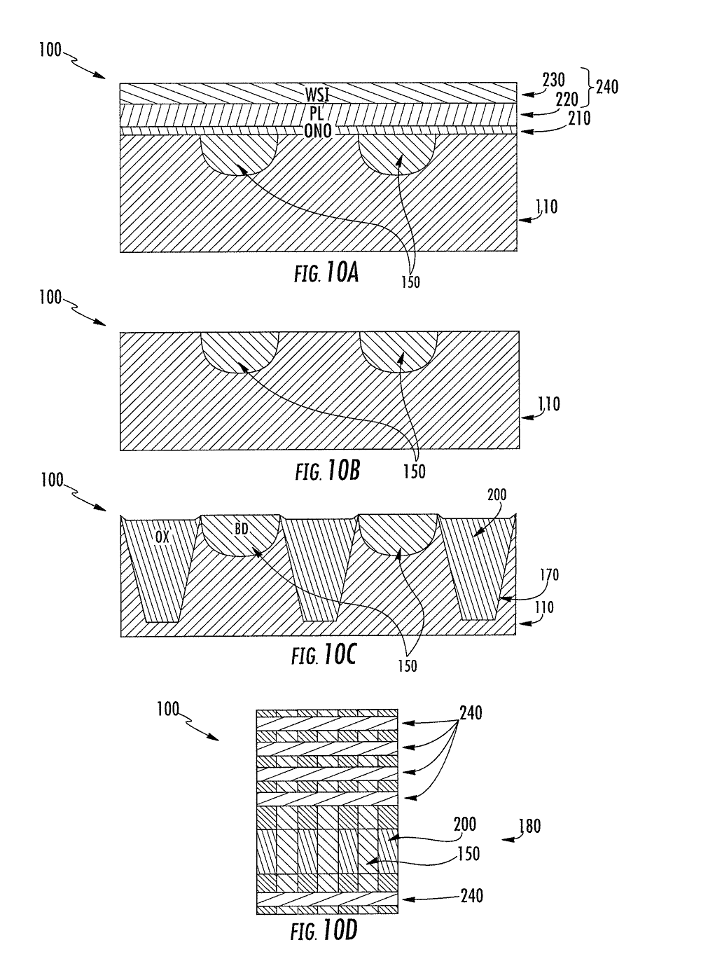

In certain embodiments of the invention, one or more word lines may be etched in the semiconductor. FIGS. 10A-10D illustrate various regions and views of a semiconductor 100 after etching a plurality of word lines 240 according to an embodiment of the invention.

In particular, FIG. 10A illustrates a cross-section of a region that remained covered by a photoresist layer during self-aligned patterning and contains a word line 240. FIG. 10B illustrates a cross-section of a region that remained covered by a photoresist layer during self-aligned patterning and does not contain a word line after etching. FIG. 10C illustrates a cross-section of the self-aligned contact region 180 of the semiconductor 100 after etching word lines 240.

FIG. 10D illustrates a top view of a semiconductor after etching word lines 240 according to an embodiment of the invention. The word lines 240 may be etched by any suitable process, such as wet or dry etching. In the embodiment of FIG. 10D, word lines 240 are etched perpendicular to the buried diffusion regions 150.

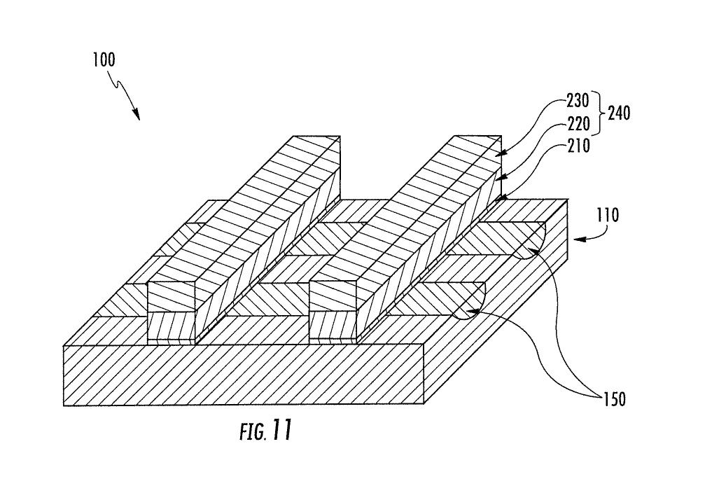

FIG. 11 is a perspective view of a portion of a semiconductor after etching at least two word lines according to an embodiment of the invention. In the embodiment of FIG. 11, word lines 240, comprising a first conductive layer 220 and a second conductive layer 230, are etched perpendicular to the buried diffusion regions 150.

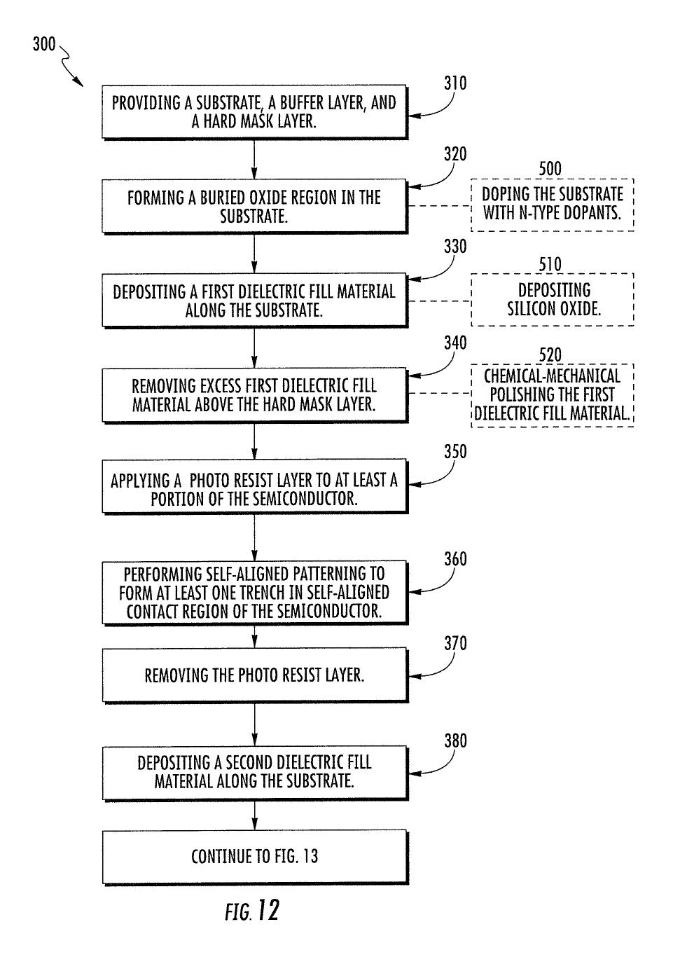

FIG. 12 illustrates a process flow chart of a method of forming a semiconductor memory device according to an embodiment of the invention. In this exemplary embodiment of the invention, the method of forming a semiconductor memory device comprises providing a substrate, a buffer layer, and a hard mask layer 310. The method shown in FIG. 12 further comprises forming a buried diffusion region in the substrate 320, depositing a first dielectric fill material along the substrate 330, and removing excess first dielectric fill material above the hard mask layer 340. In certain embodiments, the step of forming a buried diffusion region in the substrate may comprise doping the substrate with n-type dopants as illustrated in optional step 500. In certain embodiments, the step of depositing a first dielectric fill material along the substrate may comprise depositing silicon oxide as illustrated in optional step 510. In certain embodiments, the step of removing excess first dielectric fill material above the hard mask layer may comprise chemical-mechanical polishing the first dielectric fill material as illustrated in optional step 520. The embodiment illustrated in FIG. 12 further comprises applying a photo resist layer to at least a portion of the semiconductor 350, performing self-aligned patterning to form at least one trench in a self-aligned contact region of the semiconductor 360, and removing the photo resist layer 370. The method shown in FIG. 12 further comprises depositing a second dielectric fill material along the substrate 380.

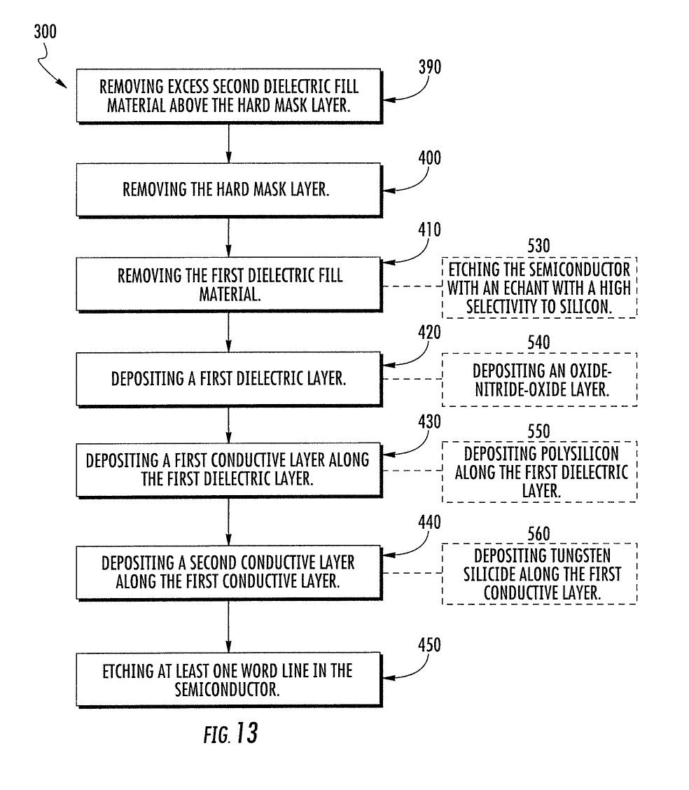

FIG. 13 illustrates a process flow chart continuing the method of forming a semiconductor memory device according to an embodiment of the invention illustrated in FIG. 12. In this exemplary embodiment of the invention shown in FIG. 13, the method of forming a semiconductor memory device further comprises removing excess second dielectric fill material above the hard mask layer 390, removing the hard mask layer 400, and removing the first dielectric fill material 410. In certain embodiments, the step of removing the first dielectric fill material may comprise etching the semiconductor with an etchant with a high selectivity to silicon as illustrated in optional step 530. The method shown in FIG. 13 further comprises depositing a first dielectric layer 420. In certain embodiments, the step of depositing a first dielectric layer may comprise depositing an oxide-nitride-oxide layer as illustrated in optional step 540. In addition, word lines are formed in this embodiment by depositing a first conductive layer along the first dielectric layer 430, depositing a second conductive layer along the first conductive layer 440, and etching at least one word line in the semiconductor 450. In certain embodiments, the step of depositing a first conductive layer along the first dielectric layer may comprise depositing polysilicon along the first dielectric layer as illustrated in optional step 550. In certain embodiments, the step of depositing a second conductive layer along the first conductive layer may comprise depositing tungsten silicide along the first conductive layer as illustrated in optional step 520. The method of the present invention may include various combinations of the steps illustrated in FIGS. 12 and 13.

The present invention may be applied to any suitable semiconductor fabrication. For instance, the method of the present invention may be applied to the fabrication of any non-volatile memory device. For instance, the method may be applied to the fabrication of Nbit memory cells.

An aspect of the invention provides a semiconductor having a memory cell fabricated using the processes or methods for fabricating a semiconductor having a memory cell of the invention. In certain other embodiments of the invention, a semiconductor device may be fabricated using any method as described herein.

Many modifications and other embodiments of the inventions set forth herein will come to mind to one skilled in the art to which these inventions pertain having the benefit of the teachings presented in the foregoing descriptions and the associated drawings. Therefore, it is to be understood that the inventions are not to be limited to the specific embodiments disclosed and that modifications and other embodiments are intended to be included within the scope of the appended claims. Although specific terms are employed herein, they are used in a generic and descriptive sense only and not for purposes of limitation.

1. A method of fabricating a semiconductor memory device comprising:
providing a substrate, a buffer layer, and a hard mask layer;
forming a buried diffusion region in the substrate;
depositing a first dielectric fill material along the substrate;
removing excess first dielectric fill material above the hard mask layer;
performing self-aligned patterning to form at least one trench in a self-aligned contact region of the semiconductor;
depositing a second dielectric fill material along the substrate;
removing excess second dielectric fill material above the hard mask layer;
removing the hard mask layer; and
removing the first dielectric fill material.

2. The method of claim 1 further comprising applying a photo resist layer to at least a portion of the semiconductor prior to performing self-aligned patterning.

3. The method of claim 2 further comprising removing the photo resist layer after performing self-aligned patterning.

4. The method of claim 1 further comprising depositing a first dielectric layer after removing the first dielectric fill material.

5. The method of claim 4 further comprising depositing a first conductive layer along the first word line dielectric layer.

6. The method of claim 5 further comprising depositing a second conductive layer along the first conductive layer.

7. The method of claim 6 further comprising etching at least one word line in the semiconductor.

8. The method of claim 1 wherein the buried diffusion region is formed by doping the substrate with n-type dopants.

9. The method of claim 1 wherein depositing the first dielectric fill material comprises depositing silicon oxide.

10. The method of claim 1 wherein removing the excess first dielectric fill material comprises chemical-mechanical polishing resulting in planarization of the first dielectric fill material.

11. The method of claim 1 wherein the removal of the first dielectric fill material comprises etching the semiconductor with an etchant with a high selectivity to silicon.

12. The method of claim 4 wherein depositing the first dielectric layer comprises depositing an oxide-nitride-oxide layer.

13. The method of claim 5 wherein depositing the first conductive layer along the first dielectric layer comprises depositing polysilicon.

14. The method of claim 6 wherein depositing the second conductive layer comprises depositing tungsten silicide.

15-20. (canceled)

21. A method of fabricating a semiconductor memory device comprising:
providing a substrate, a buffer layer, and a hard mask layer;
forming a buried diffusion region in the substrate;
depositing a first dielectric fill material along the substrate;
removing excess first dielectric fill material above the hard mask layer;
forming at least one trench in the semiconductor;
removing the first dielectric fill material; and
forming a word line along the substrate.

22. The method of claim 21 further comprising depositing a second dielectric fill material after forming at least one trench in the semiconductor.

23. The method of claim 22 further comprising removing excess second dielectric fill material.

24. The method of claim 21 further comprising removing the hard mask later prior to removing the first dielectric fill material.

25. The method of claim 21, wherein forming a word line along the substrate comprises forming a first conductive layer and a second conductive layer.

26. The method of claim 25, wherein the first conductive layer comprises polysilicon and the second conductive layer comprises tungsten silicide.
